(19) United States
(12) Patent Application Publication
(10) Pub. No.: US 2020/0081162 A1
(43) Pub. Date: Mar. 12, 2020

(54) FLEXIBLE WINDOW AND FLEXIBLE DISPLAY DEVICE COMPRISING THE SAME

(71) Applicant: Samsung Display Co., Ltd., Yongin-si (KR)

(72) Inventors: Young Sang PARK, Seoul (KR); Sung Guk AN, Suwon-si (KR); Chul Ho JEONG, Seoul (KR)

(21) Appl. No.: 16/459,272

(22) Filed: Jul. 1, 2019

(30) Foreign Application Priority Data
Sep. 12, 2018 (KR) 10-2018-0108836

(51) Int. Cl. G02B 1/14; G02B 5/30; H01L 51/52

(52) U.S. Cl. CPC G02B 1/14; G02B 5/3083; H01L 27/3244; H01L 2251/5338; H01L 51/5253

(57) ABSTRACT

A flexible window providing apparatus is provided. A flexible window includes: a retardation layer; an impact mitigation layer disposed on the retardation layer; and a surface layer disposed on the impact mitigation layer. The retardation layer includes a λ/4 retardation plate.

This application claims priority to and the benefit of Korean Patent Application No. 10-2018-0108836, filed on Sep. 12, 2018, the disclosure of which is incorporated herein by reference in its entirety.

### BACKGROUND

### 1. Field

The present disclosure relates to a flexible window and a flexible display device including the same.

### 2. Description of the Related Art

Examples of display devices include a liquid-crystal display device, an organic light-emitting display device, etc.

Unlike a liquid-crystal display device, an organic light-emitting display device does not require a backlight unit and thus can be made thinner. Therefore, flexible, stretchable, foldable, bendable and/or rollable organic light-emitting display devices are under study (e.g., being studied).

Such a flexible display device may employ a flexible window on a display panel where images are displayed, thereby protecting the display device while having flexibility (e.g., while being flexible).

### SUMMARY

When a transparent plastic film instead of glass is employed in order to give flexibility to the flexible window, the flexible display device may be vulnerable to an external impact. In addition, when a viewer wears polarized sunglasses, a blackout may occur at a particular angle, and a rainbow-like stain, so-called “rainbow mura,” may occur on the surface of the display device. As a result, the image quality may be degraded.

Aspects of the present disclosure are directed toward a flexible window achieving impact resistance as well as flexibility, and a flexible display device including the same.

Aspects of the present disclosure are also directed toward a flexible window capable of preventing or reducing black out and rainbow mura even when a viewer wears polarized sunglasses, and a flexible display device including the same.

It should be noted that aspects of the present disclosure are not limited to the above-mentioned aspects; and other aspects of the present invention will be apparent to those skilled in the art from the following descriptions.

According to an exemplary embodiment of the present disclosure, it is possible to achieve impact resistance as well as flexibility while improving display quality.

According to an embodiment of the present disclosure, a flexible window includes: a retardation layer; an impact mitigation layer on the retardation layer; and a surface layer on the impact mitigation layer, wherein the retardation layer includes a λ/4 retardation plate.

According to another embodiment of the present disclosure, a flexible window includes: a high-retardation layer; and a surface layer on the high-retardation layer, wherein the surface layer includes a base layer, a hard coating layer on the base layer, and an anti-fingerprint coating layer on the hard coating layer, and wherein an in-plane retardation of the high-retardation layer is from 6,000 nm to 10,000 nm.

According to still another embodiment of the present disclosure, a flexible display device includes: a display panel; a flexible window on the display panel; and a pressure sensitive adhesive (PSA) between the display panel and the flexible window, wherein the flexible window includes a retardation layer, an impact mitigation layer on the retardation layer and a surface layer on the impact mitigation layer, and wherein the retardation layer includes a λ/4 retardation plate.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in more detail exemplary embodiments thereof with reference to the attached drawings, in which:

FIG. 1 is a cross-sectional view showing a stack structure of a flexible display device according to an exemplary embodiment of the present disclosure;

FIG. 2 is an enlarged cross-sectional view of portion A of the flexible display device shown in FIG. 1;

FIG. 3 is a diagram for illustrating a principle for preventing or reducing a blackout phenomenon by employing the retardation layer according to an exemplary embodiment of the present disclosure;

FIG. 4 is a cross-sectional view showing a stack structure of a flexible window according to another exemplary embodiment of the present disclosure;

FIGS. 5A to 5C are graphs for illustrating retardation versus wavelength of a high-retardation film in a visible light range;

FIG. 6 is a cross-sectional view showing a stack structure of a flexible window according to another exemplary embodiment of the present disclosure;

FIG. 7 is a cross-sectional view showing a stack structure of a flexible window according to another exemplary embodiment of the present disclosure;

FIG. 8 is a cross-sectional view showing a stack structure of a flexible window according to yet another exemplary embodiment of the present disclosure;

FIG. 9 is a cross-sectional view showing a stack structure of a flexible window according to yet another exemplary embodiment of the present disclosure; and

FIG. 10 is a cross-sectional view showing a stack structure of a flexible window according to yet another exemplary embodiment of the present disclosure.

### DETAILED DESCRIPTION

Features of the inventive concept and methods of accomplishing the same may be understood more readily by reference to the following detailed description of embodiments and the accompanying drawings. The inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the inventive concept will only be defined by the appended claims. Like reference numerals refer to like elements throughout the specification.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations), and the spatially relative descriptors used herein may be interpreted accordingly.

Unless otherwise defined, all terms (including technical and scientific terms) used herein have the same meaning as commonly understood by one of ordinary skill in the art to which the present application belongs. It will be further understood that terms, such as those defined in commonly used dictionaries, should be interpreted as having a meaning that is consistent with their meaning in the context of the relevant art and this specification and will not be interpreted in an idealized or overly formal sense, unless expressly so defined herein.

The same or similar parts throughout the specification are denoted by the same reference numerals.

Exemplary embodiments of the present disclosure will hereinafter be described with reference to the accompanying drawings.

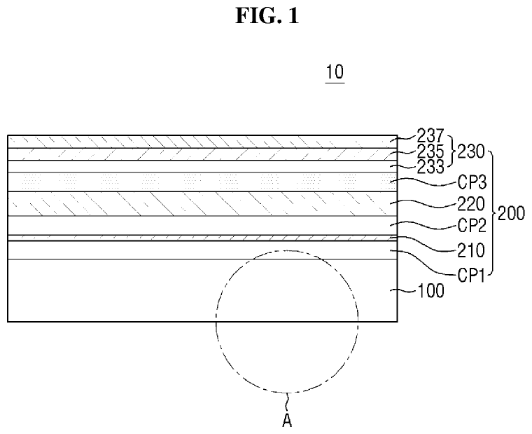

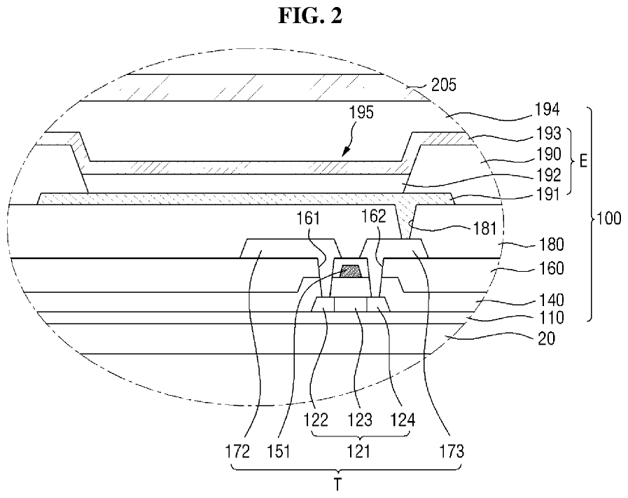

FIG. 1 is a cross-sectional view schematically showing a stack structure of a flexible display device according to an exemplary embodiment of the present disclosure. FIG. 2 is an enlarged cross-sectional view of portion A of the flexible display device shown in FIG. 1.

Referring to FIGS. 1 and 2, the flexible display device 10 includes a display panel 100 and a flexible window 200 disposed on the display panel 100.

The display panel 100 may include a flexible substrate 20, a buffer layer 110, an active layer 121, a gate insulating layer 140, a gate electrode 151, an interlayer dielectric layer 160, a source electrode 172, a drain electrode 173, a passivation layer 180, an organic light-emitting element E, and an encapsulation layer 194.

The flexible substrate 20 may work as a base substrate of the display panel 100. The flexible substrate 20 can have the flexible property (e.g., may be flexible) so that the flexible display device can display images even when it is bent. To this end, the flexible substrate 20 may be formed thin and may include a material having elasticity.

In an exemplary embodiment, the flexible substrate 20 may include, but is not limited to, polyimide. For example, it may include a flexible glass and/or the like.

The buffer layer 110 is disposed on the flexible substrate 20. The buffer layer 110 may be formed directly on the flexible substrate 20. The buffer layer 110 may include silicon nitride (SiNx), silicon oxide (SiOx), silicon oxynitride (SiOxNy), and/or the like, and may be made up of a single layer or multiple layers. The buffer layer 110 prevents or reduces permeation of impurities, moisture or outside air, which degrades the characteristics of the semiconductor, and/or provides a flat surface.

The active layer 121 is disposed on the buffer layer 110. The active layer 121 may include a semiconductor and may be formed of polysilicon.

The active layer 121 may include a channel region 123, and a source region 122 and a drain region 124 located on both sides of the channel region 123, respectively. The channel region 123 may be an intrinsic semiconductor that is polycrystalline silicon not doped with impurities. The source region 122 and the drain region 124 may be impurity semiconductors that are polycrystalline silicon doped with conductive impurities.

The gate insulating layer 140 is disposed on the active layer 121. The gate insulating layer 140 may be formed of an insulating layer including silicon nitride, silicon oxide, silicon oxynitride, and/or the like, and may be made up of a single layer or multiple layers.

The gate electrode 151 is disposed on the gate insulating layer 140. The gate electrode 151 may be connected to the gate line and the gate pad. The gate electrode 151 may include aluminum (Al), molybdenum (Mo), copper (Cu), or an alloy thereof, and may have a multilayer structure.

The interlayer dielectric layer 160 is disposed on the gate electrode 151. The interlayer dielectric layer 160 may be formed of an insulating layer including silicon nitride, silicon oxide, silicon oxynitride, and/or the like, and may be made up of a single layer or multiple layers.

The source electrode 172 and the drain electrode 173 are disposed on the interlayer dielectric layer 160. The source electrode 172 may be disposed such that it overlaps with the source region 122 of the active layer 121, and the drain electrode 173 may be disposed such that it overlaps with the drain region 124 of the active layer 121. The source electrode 172 and the drain electrode 173 may be connected to the data line and the data pad described above.

A data metal layer (e.g., data line, data pad, etc.,) may include aluminum (Al), molybdenum (Mo), chromium (Cr), tantalum (Ta), titanium (Ti), other refractory metals, or alloys thereof, and may also have a multilayer structure.

In the gate insulating layer 140 and the interlayer dielectric layer 160, a source contact hole 161 and a drain contact hole 162 may be formed which electrically connect the source electrode 172 and the drain electrode 173 to the source region 122 and the drain region 124 of the active layer 121, respectively.

The active layer 121, the gate electrode 151, the source electrode 172, and the drain electrode 173 of the flexible display device 10 may form a thin film transistor T. The gate electrode 151, which is the control terminal of the thin-film transistor T, may be connected to the gate line; the source electrode 172, which is the input terminal, may be connected to the data line; and the drain electrode 173, which is the output terminal, may be electrically connected to the anode electrode 191 through a contact hole 181.

The passivation layer 180 is formed over the source electrode 172 and the drain electrode 173. The passivation layer 180 may include silicon nitride, silicon oxide, silicon oxynitride, an acryl-based organic compound having a small dielectric constant, benzocyclobutane (BCB), perfluorocyclobutane (PFCB), and/or the like.

The passivation layer 180 may protect the source electrode 172 and the drain electrode 173, and may work as a planarization layer to provide a flat upper surface. In the passivation layer 180, the contact hole 181 may be formed via which the drain electrode 173 is exposed.

The organic light-emitting element E is disposed on the passivation layer 180. The organic light-emitting element E may include an anode electrode 191, a pixel defining layer 190, an organic emissive layer 192, and a cathode electrode 193.

The anode electrode 191 is disposed at the bottom of the organic light-emitting element E. The anode electrode 191 may be electrically connected to the drain electrode 173 through the contact hole 181 formed in the passivation layer 180, and may be a pixel electrode of the organic light-emitting device E.

The anode electrode 191 may include a material layer having a high work function, such as ITO, IZO, ZnO and/or In₂O₃. Furthermore, the anode electrode 191 may be implemented as a stack of layers including the above-described material layer having a high work function and a reflective metal layer, such as lithium (Li), calcium (Ca), lithium fluoride/calcium (LiF/Ca), lithium fluoride/aluminum (LiF/Al), aluminum (Al), silver (Ag), magnesium (Mg), and/or gold (Au).

The pixel defining layer 190 is disposed on the anode electrode 191. The pixel defining layer 190 may include a resin, such as polyacrylates and/or polyimides. The pixel defining layer 190 serves to separate each pixel of the organic light-emitting element E, and may include an opening 195 through which the anode electrode 191 is exposed.

The organic emissive layer 192 is disposed on the anode electrode 191 exposed through the opening 195 of the pixel defining layer 190. The organic emissive layer 192 may be implemented as multiple layers including one or more of a hole injection layer (HIL), a hole transport layer (HTL), an electron transport layer (ETL), an electron injection layer (EIL), and an emissive layer (EML).

The cathode electrode 193 is disposed on the pixel defining layer 190 and the organic emissive layer 192. The cathode electrode 193 may include Li, Ca, LiF/Ca, LiF/Al, Al, Mg, Ag, Pt, Pd, Ni, Au, Nd, Ir, Cr, BaF, Ba, a compound thereof, or a mixture thereof (e.g., a mixture of Ag and Mg). The cathode electrode 193 may be the common electrode of the organic light-emitting element E.

The encapsulation layer 194 is disposed on the cathode electrode 193. The encapsulation layer 194 may prevent or reduce moisture or air from permeating from the outside to oxidize the organic light-emitting element E, and may also provide a flat surface.

In an exemplary embodiment, the display panel 100 may further include a touch sensing unit (e.g., a touch sensor) attached thereto or incorporated thereinto. For example, the touch sensing unit may be interposed between the encapsulation layer 194 and the window 200, and the touch sensing unit acquires the coordinate information of a point where an input has been made. The touch sensing unit may be disposed on the entire surface of the display panel 100. However, the positional relationship between the display panel 100 and the touch sensing unit is not limited thereto. The touch sensing unit may be of a contact touch sensing unit or a non-contact touch sensing unit. A resistance touch sensing unit, an electromagnetic induction touch sensing unit, and/or a capacitance touch sensing unit may be employed (e.g., utilized), and the kind of touch sensing unit is not particularly limited thereto.

The display panel 100 may further include a polarizing unit (e.g., a polarizer) disposed between the touch sensing unit and the encapsulation layer 194, but the present disclosure is not limited thereto. The polarizing unit disposed between the touch sensing unit and the encapsulation layer 194 may be eliminated (e.g., not included).

The flexible window 200 is disposed on the display panel 100 to protect the display panel 100 from physical impact and permeation of outside air, and may provide flexibility to the flexible display device 10.

The flexible window 200 may include a retardation layer 210 disposed on the display panel 100, an impact mitigation layer 220 disposed on the retardation layer 210, and a surface layer 230 disposed on the impact mitigation layer 220.

The retardation layer 210 may have the retardation of a quarter-wave (λ/4) and may include a quarter-wave plate (QWP) that converts linearly-polarized light into circularly-polarized light, or vice versa. However, the present disclosure is not limited thereto. A λ/4 retardation film, such as a reactive mesogen film, may also be employed. The retardation layer 210 is utilized to convert linearly-polarized light output from the display panel 100 into circularly-polarized light. By doing so, when a viewer wears polarized sunglasses, it is possible to prevent or reduce the blackout phenomenon that occurs when the light output from the display panel 100 coincides with the absorption axis of the polarized sunglasses such that the light is not visible, and to prevent or reduce the color distortion phenomenon that occurs due to the retardation of the surface layer 230, where the lights of different wavelength bands, i.e., light of different colors, are transmitted in a pattern which look like a rainbow.

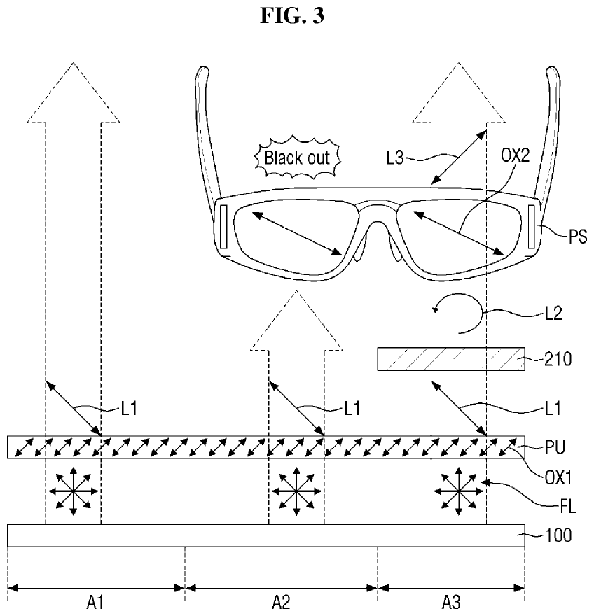

FIG. 3 is a diagram for illustrating a principle for preventing or reducing a blackout phenomenon by employing the retardation layer according to an exemplary embodiment of the present disclosure. Referring to FIG. 3, a light FL outputted from the display panel 100 passes through a polarizing unit PU and is polarized such that a first linearly-polarized light L1 perpendicular to a first absorption axis OX1 of the polarizing unit PU is the output. The first linearly-polarized light L1 can be seen by viewer's eyes (A1).

On the other hand, when a viewer wears polarized sunglasses PS with a second absorption axis OX2 of the polarized sunglasses PS perpendicular to the first absorption axis OX1 of the polarizing unit PU, the first linearly-polarized light L1 cannot pass through the polarized sunglasses PS. Accordingly, the viewer may see a block out (A2). In contrast, when the retardation layer 210 according to embodiments of the present disclosure is disposed between the polarizing unit PU and the polarized sunglasses PS, the first linearly-polarized light L1 is retarded by λ/4, such that the first linearly-polarized light L1 is converted into a circularly-polarized light L2 and then the circularly-polarized light L2 is converted into a second linearly-polarized light L3 through the polarized sunglasses PS. The second linearly-polarized light L3 can be seen by the viewer's eyes (A3). In addition, as the first linearly-polarized light L1 is converted into the circularly-polarized light L2, it is possible to prevent or substantially prevent a rainbow-like stain, i.e., a rainbow mura, due to the retardation of the surface layer 230. In this manner, it is possible to effectively prevent or reduce the blackout phenomenon and the color distortion caused when a viewer wears the polarized sunglasses PS. In other words, a viewer can watch the images on the display device 10 stably with or without the polarized sunglasses PS.

Referring back to FIGS. 1 and 2, according to an exemplary embodiment, a first coupling part CP1 may be disposed between the retardation layer 210 and the display panel 100. The first coupling part CP1 may be implemented as (e.g., may be) an optically clear adhesive (OCA) film, an optically clear resin (OCR), and/or the like. In another exemplary embodiment, the first coupling part CP1 may be a pressure-sensitive adhesive (PSA). The pressure-sensitive adhesive may be made of acryl and/or silicone (Si). The thickness of the pressure-sensitive adhesive may range from 25 to 50 μm, and the releasing force (peeling force) may be 16 gf/in to 35 gf/in. However, the present disclosure is not limited thereto. The first coupling part CP1 may serve to attach and fix the retardation layer 210 to the display panel 100.

The first coupling part CP1 may be disposed on the entire surface area where the retardation layer 210 overlaps with the display panel 100. However, the present disclosure is not limited thereto. The first coupling part CP1 may be disposed only in a part of the area where the retardation layer 210 overlaps with the display panel 100. For example, the first coupling part CP1 may be disposed along the edge of the area where the retardation layer 210 overlaps with the display panel 100. A number of first coupling parts CP1 may be disposed in the area where the retardation layer 210 overlaps with the display panel 100 such that they are spaced apart from one another in the form of bars and/or dots.

When a sharp object, such as a pen, exerts an impact on the surface of the flexible window 200, a crack may occur on the surface. This may degrade the display quality and durability. In order to prevent or reduce such defects, it is desirable to improve the impact resistance of the entire flexible window 200. To this end, the flexible window 200 may include an impact mitigation layer 220. In an exemplary embodiment, the impact mitigation layer 220 may be disposed above the retardation layer 210.

The impact mitigation layer 220 may be made up of a single layer or multiple layers. The impact mitigation layer 220 may include a material that has elasticity to mitigate the impact by delaying the time in which the impact force is transmitted.

In an exemplary embodiment, the impact mitigation layer 220 may be made of a polyurethane-based material. However, the present disclosure is not limited thereto. The impact mitigation layer 220 may be made of polydimethylsiloxane (PDMS), rubber, and/or the like. The impact mitigation layer 220 can mitigate the impact force from the outside and may be transparent and flexible.

By adjusting the thickness and the tensile modulus of the impact mitigation layer 220 included in the flexible window 200, it is possible to increase the period of time in which the impact force by the impact is transmitted. However, the thickness of the impact mitigation layer 220 cannot be increased infinitely as the overall thickness is limited and the radius of curvature is also limited. In view of the above, the thickness of the impact mitigation layer 220 included in the flexible window 200 may be in a range from 70 μm and 150 μm. That is, the impact mitigation layer 220 can mitigate impact force from the outside sufficiently if the thickness is 70 μm or larger. In addition, it is possible to suppress cracks if the thickness is 150 μm or smaller. Accordingly, the thickness of the impact mitigation layer 220 may be, but is not limited to, 70 μm to 150 μm.

In order to check the impact resistance of the impact mitigation layer 220, a drop test was carried out by dropping a pen onto a test object. The drop test was carried out with Bic® Orange™ FINE ballpoint pens having the dot diameter of 0.7 mm and the weight of 5.8 g. The drop test was carried out by increasing the drop height by 1 centimeter (cm) whenever a test object passed the test and repeated it until the test object fails to pass (e.g., showing cracks). Results of the drop test are shown in Table 1 below:

TABLE 1

| | Thickness of Impact Mitigation Layer (μm) | | | | | |
|---|---|---|---|---|---|---|
| | 60 | 70 | 80 | 100 | 150 | 160 |
| Pen Drop Height | 1 | 6 | 7 | 9 | 12 | 13 |
| Passed Test (cm) | | | | | | |
| Folding Character- | OK | OK | OK | OK | OK | Buckling |
| istics (Curvature | | | | | | |
| 3R In/Out) | | | | | | |

It can be seen from Table 1 that the highest pen drop height that passes the test increases with the thickness of the impact mitigation layer 220. However, when the impact mitigation layer 200 has the thickness of 160 μm, buckling occurs on the interface between the impact mitigation layer 220 and the retardation layer 210 or the interface between the impact mitigation layer 220 and the surface layer 230 when the display device is folded. It can also be seen that the pen drop height that passes the test rapidly decreases when the thickness of the impact mitigation layer 220 is less than 70 μm. In other words, it can be seen that the impact mitigation layer 220 should have a thickness of 70 μm or larger in order to have a sufficient safe drop height. Therefore, in one embodiment, the thickness of the impact mitigation layer 220 is 70 μm or more. Although the drop height increases with the thickness of the impact mitigation layer 220, buckling may occur when the display device is folded if the thickness is too large. Therefore, the thickness of the impact mitigation layer 220 may be determined to be within the range to allow for flexibility, e.g., 150 μm or smaller. However, the present disclosure should not be limited thereto.

In order to compare the surface hardness of the impact mitigation layer 220, the hardness of pencils were measured by applying the load of 500 g utilizing a pencil hardness tester (PHT, available from Sukbo-science Corporation in Republic of Korea). The pencils with the hardness from 6B to 9H were utilized to scratch the surface at the angle of 45 degrees, and the surface was observed after the test. The hardness of the lead of each of the pencils was measured (e.g., recorded) when a scratch is made (e.g., observed) after five trials (e.g., repeated five times). Results of the pencil hardness test are shown in Table 2 below:

TABLE 2

| | Tensile modulus of Impact Mitigation Layer (GPa) | | | | |
|---|---|---|---|---|---|
| | 0.05 | 0.01 | 0.25 | 0.5 | 0.5< |
| Pencil Hardness | 3B | H~3H | H~3H | H~3H | 4H |
| (Module structure) | | | | | |
| Folding Character- | OK | OK | OK | OK | Buckling |
| istics (Curvature | | | | | |
| 3R In/Out) | | | | | |

Referring to Table 2, it can be seen that the surface hardness of the impact mitigation layer 220 increases with the tensile modulus of the impact mitigation layer 220. It is to be noted that when the tensile modulus of the impact mitigation layer 220 exceeds 0.5 GPa, buckling occurs on the interface between the impact mitigation layer 220 and the retardation layer 210 or the interface between the impact mitigation layer 220 and the surface layer 230. It can also be seen that the surface hardness drops to 3B when the tensile modulus of the impact mitigation layer 220 is less than 0.01 GPa. When the tensile modulus of the impact mitigation layer 220 is high, although the hardness is excellent, it is more likely that buckling may occur due to the difference in shear stress with another layer (e.g., an adjacent layer) when it is stacked on it. When the tensile modulus is low, on the other hand, although impact absorption is excellent, it may be difficult to handle. According to an exemplary embodiment of the present disclosure, the tensile modulus of the impact mitigation layer 220 may be in a range from 0.01 GPa to 0.5 GPa. By disposing the impact mitigation layer 220 having a tensile modulus of 0.01 GPa to 0.5 GPa in the flexible window 200 as described above, the impact resistance of the flexible window 200 can be improved and buckling can be suppressed.

The in-plane retardation value Re and the retardation value Rth of the impact mitigation layer 220 in the thickness direction can be expressed as refractive indices in the directions in the xyz coordinate system. For example, if the impact mitigation layer 220 is located in the xy plane, the x-axis and y-axis refer to the planar direction of the impact mitigation layer 220, and the z-axis refers to the thickness direction. That is, the impact mitigation layer 220 has refractive indices of nx, ny and nz along the x-axis, the y-axis and the z-axis, respectively. The Re denotes a retardation value in the plane direction, and Rth denotes a retardation value in the thickness direction. The Nz denotes the degree of biaxiality.

The relationship of the above-described values can be expressed by Equations 1 to 3 below:

Re=(nx−ny)*d Equation 1

Rth=((nx+ny)/2−nz)*d Equation 2

Nz=Rth/Ro Equation 3

wherein nx, ny and nz each represent the refractive index along the x-axis, the y-axis and the z-axis, respectively, and d denotes the thickness of the film.

According to an exemplary embodiment of the present disclosure, the in-plane retardation value Re and the retardation value Rth of the impact mitigation layer 220 in the thickness direction may be, but is not limited to, zero.

According to another exemplary embodiment, the impact mitigation layer 220 may be disposed in the form of a film. For example, the film may include one or more of colorless polyimide (CPI), thermoplastic polyurethane (TPU), tri-acetyl-cellulose film (TAC film), polycarbonate (PC), polymethyl methacrylate (PMMA), cyclo olefinpolymer (COP), polyurethane, silicone, polyethylene terephthalate (PET), polyethylene (PE) and oriented polypropylene (OPP). When the impact mitigation layer 220 is implemented in the form of a film, the impact mitigation layer 220 can be disposed as a thin film, which is desirable in that the thickness of the flexible window 200 can be reduced. The above-described impact resistance test was carried out on the impact mitigation layer 220 in the form of a film. The results of the test are shown in Table 3 below:

TABLE 3

| | Thickness of Impact Mitigation Layer (μm) | | | | |
|---|---|---|---|---|---|
| | 20 | 30 | 50 | 80 | 90 |
| Pen Drop Height | 0.5 | 3 | 5 | 7 | 8 |
| Passed Test (cm) | | | | | |
| Folding Character- | OK | OK | OK | OK | Buckling |
| istics (Curvature | | | | | |
| 3R In/Out) | | | | | |

It can be seen from Table 3 that the highest pen drop height that passes the test increases with the thickness of the impact mitigation layer 220 in the form of a film. However, when the impact mitigation layer 200 has the thickness of 90 μm, buckling occurs on the interface between the impact mitigation layer 220 and the retardation layer 210 or the interface between the impact mitigation layer 220 and the surface layer 230 when the display device is folded. It can also be seen that the pen drop height that passes the test rapidly decreases when the thickness of the impact mitigation layer 220 is less than 30 μm. In other words, it can be seen that the impact mitigation layer 220 should have a thickness of 30 μm or larger in order to achieve a sufficient drop height. Therefore, in one embodiment, the thickness of the impact mitigation layer 220 is 30 μm or more. Although the drop height increases with the thickness of the impact mitigation layer 220, buckling may occur when the display device is folded when the thickness is too large. Therefore, the thickness of the impact mitigation layer 220 may be determined to be within the range to allow for flexibility, e.g., 80 μm or smaller. However, the present disclosure is not limited thereto.

When the tensile modulus of the impact mitigation layer 220 in the form of a film is high, although the hardness is excellent, it is more likely that buckling may occur due to the difference in shear stress with another layer (e.g., an adjacent layer) when it is stacked on it. When the tensile modulus is low, on the other hand, although impact absorption is excellent, it may be difficult to handle. A pencil lead test was carried out on the impact mitigation layer 220 in the form of a film. The results of the test are shown in Table 4 below:

TABLE 4

| | Tensile modulus of Impact Mitigation Layer (GPa) | | | | | |
|---|---|---|---|---|---|---|
| | 0.5 | 1.0 | 3.0 | 5.0 | 6.0 | 7.0 |
| Pencil Hardness | 3B | B | H | 2H | 3H | 5H |
| (Module structure) | | | | | | |
| Folding Character- | OK | OK | OK | OK | Buckling | Buckling |
| istics (Curvature | | | | | | |
| 3R In/Out) | | | | | | |

Referring to Table 4, it can be seen that the surface hardness of the impact mitigation layer 220 in the form of a film increases with the tensile modulus of the impact mitigation layer 220. It is to be noted that when the tensile modulus of the impact mitigation layer 220 exceeds 5 GPa, buckling occurs on the interface between the impact mitigation layer 220 in the form of a film and the retardation layer 210 or the interface between the impact mitigation layer 220 and the surface layer 230. It can also be seen that the surface hardness drops to 3B when the tensile modulus of the impact mitigation layer 220 is less than 1.0 GPa. According to an exemplary embodiment of the present disclosure, the tensile modulus of the impact mitigation layer 220 in the form of a film may be in a range from 1 GPa to 5 GPa. By disposing the impact mitigation layer 220 having a tensile modulus of 1 GPa to 5 GPa in the flexible window 200 as described above, the impact resistance of the flexible window 200 can be improved and buckling can be suppressed.

In an exemplary embodiment, a second coupling layer part CP2 may be disposed between the impact mitigation layer 220 and the retardation layer 210. The second coupling part CP2 may be implemented as, but is not limited to, an optically clear adhesive (OCA) film, an optically clear resin (OCR), and/or the like. The second coupling part CP2 may serve to attach and fix the impact mitigation layer 220 to the retardation layer 210.

The second coupling part CP2 may be disposed on the entire surface area where the impact mitigation layer 220 overlaps with the retardation layer 210. However the present disclosure is not limited thereto. The second coupling part CP2 may be disposed only on a part of the area where the impact mitigation layer 220 overlaps with the retardation layer 210. For example, the second coupling part CP2 may be disposed along the edge of the area where the impact mitigation layer 220 overlaps with the retardation layer 210. A number of second coupling parts CP2 may be disposed in the area where the impact mitigation layer 220 overlaps with the retardation layer 210 such that they are spaced apart from one another in the form of bars or dots.

The surface layer 230 may be disposed on the impact mitigating layer 220. The surface layer 230 may include a base layer 233, a hard coating layer (e.g, a hard-coat layer) 235 disposed on the base layer 233 and an anti-fingerprint coating layer 237 disposed on the hard coating layer 235.

The base layer 233 may include, but is not limited to, polyimide (PI). For example, it may include a polymer material such as polyethylene terephthalate (PET), polycarbonate (PC), and polymethylmethacrylate (PMMA). In consideration of flexibility and durability, the thickness of the base layer 233 may be in a range from 5 μm to 50 μm, and the tensile modulus may be in a range from 3.5 GPa to 7 GPa. However, the present disclosure is not limited thereto.

The hard coating layer 235 may be made of a material having a high hardness. The hard coating layer 235 may have certain flexibility so that it can be bent or folded. Because the hard coating layer 235 may be the top layer directly exposed to the outside, it is also required to have good resistance to chemicals and corrosion. To this end, the hard coating layer 235 may include an acrylic compound, an epoxy compound, an organic/inorganic complex compound, or a combination thereof. However, the present disclosure is not limited thereto. The hard coating layer 235 may include an ultraviolet ray-curing resin other than an acrylic compound and/or an epoxy compound. The hard coating layer 235 may have a thickness of 5 μm to 10 μm, a tensile modulus of 3 GPa to 5 GPa, and a micro hardness of 50 HV or more. However, the present disclosure is not limited thereto. Because the correlation between the micro hardness and the Vickers hardness is known in the art, the micro hardness can be converted into the Vickers hardness.

The hard coating layer 235 may be formed on the base layer 233 by coating, for example. The hard coating layer 235 may be formed by, for example, slip coating, bar coating, spin coating, etc. By doing so, the hard coating layer 235 can be thinly formed on the base layer 233, allowing for easy bending and/or folding.

The anti-fingerprint coating layer 237 may contain a fluorine (F)-containing compound. Accordingly, it is possible to prevent or substantially prevent interference from the outside to the flexible window 200, and prevent or substantially prevent foreign matter from being adsorbed onto the flexible window 200.

In an exemplary embodiment, a third coupling part CP3 may be disposed between the impact mitigation layer 220 and the surface layer 230. The third coupling part CP3 may be implemented as, but is not limited to, an optically clear adhesive (OCA) film, an optically clear resin (OCR), and/or the like. The third coupling part CP3 may serve to attach and fix the impact mitigation layer 220 to the base layer 233 of the surface layer 230.

The third coupling part CP3 may be disposed on the entire surface area where the impact mitigation layer 220 overlaps with the base layer 233 of the surface layer 230. However, the present disclosure is not limited thereto. The third coupling part CP3 may be disposed only on a part of the area where the impact mitigation layer 220 overlaps with the base layer 233 of the surface layer 230. For example, the third coupling part CP3 may be disposed along the edge of the area where the impact mitigation layer 220 overlaps with the base layer 233 of the surface layer 230. A number of third coupling parts CP3 may be disposed in the area where the impact mitigation layer 220 overlaps with the base layer 233 of the surface layer 230 such that they are spaced apart from one another in the form of bars or dots.

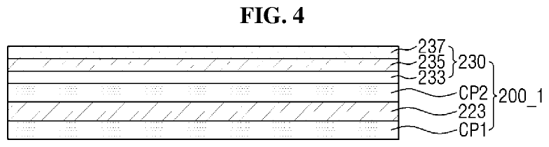

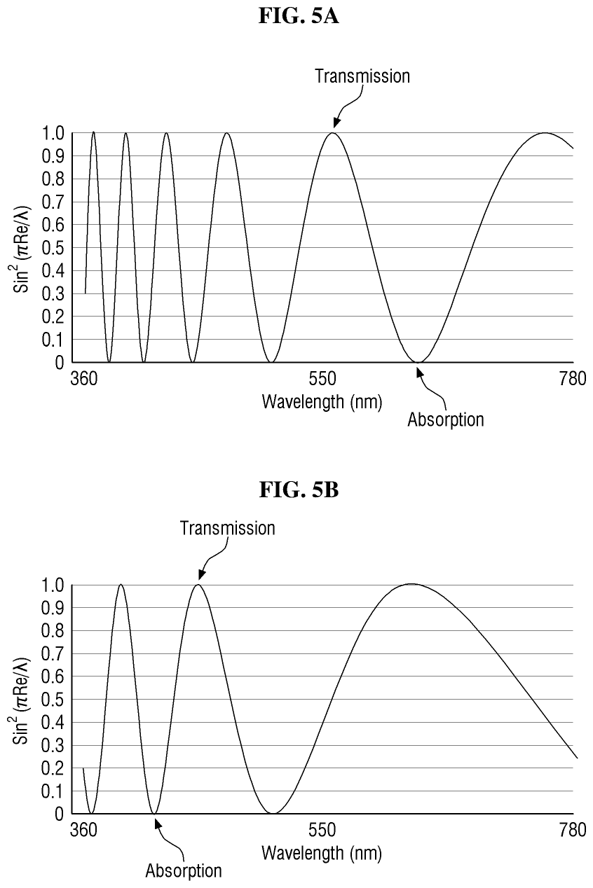

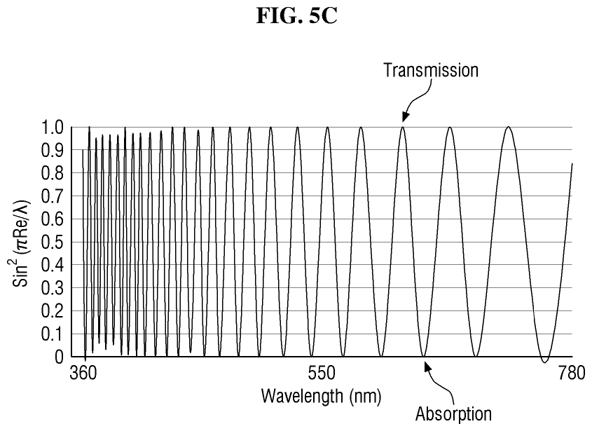

FIG. 4 is a cross-sectional view showing a stack structure of a flexible window according to another exemplary embodiment of the present disclosure. FIGS. 5A to 5C are graphs for illustrating retardation versus wavelength of a high-retardation film in a visible light range.

Referring to FIG. 4, a flexible window 200_1 according to another exemplary embodiment may include a high-retardation layer 223 disposed on the display panel 100 (see FIG. 1), and a surface layer 230 disposed on the high-retardation layer 223.

In an exemplary embodiment, the high-retardation layer 223 may be implemented as, but is not limited to, a high-retardation film. The high-retardation film working as the high-retardation layer 223 according to the exemplary embodiment of the present disclosure may have an in-plane retardation in the range of 6,000 nm to 10,000 nm.

The high-retardation film may include at least one of: a cyclo-olefin polymer (COP) film, a cyclo-olefin co-polymer (COC) film, a polycarbonate (PC) film, a polyethylene terephthalate (PET) film, a polypropylene (PP) film, a polysulfone (PSF) film, and a polymethylmethacrylate (PMMA) film.

FIG. 5A is a graph showing the distribution of transmitted light according to the retardation versus wavelength of a PET film in a visible light range. FIG. 5B is a graph showing the distribution of transmitted light according to the retardation versus wavelength of a PI film in a visible light range. FIG. 5C is a graph showing the distribution of transmitted light according to the retardation versus wavelength of a high-retardation film in a visible light range.

Referring to FIGS. 5A and 5B, when the light, which is output from the display panel 100 (see FIG. 3) and passes through the polarizing unit PU (see FIG. 3) to be linearly polarized, passes through the PET film or the PI film, because the PET film and/or the PI film has a retardation phenomenon, a rainbow mura phenomenon occurs as the transmitted light has retardation over wavelengths in the visible light range. That is, the linearly-polarized light incident on and passing through the PET film and/or the PI film causes retardation over wavelengths. The graphs show the retardation versus wavelength (i.e., the retardation expressed in the length of wavelength λ (lambda)). When the retardation occurs (e.g., is caused) by the PET film and/or the PI film, different wavelengths have different retardations versus wavelength of the visible light. In addition, it can be seen that as the retardation of the PET film and/or the PI film varies, the retardation versus wavelength for each of the wavelengths varies. For example, the wavelength coincident with the absorption axis OX1 (see FIG. 3) of the polarizing unit PU (see FIG. 3) becomes shorter from 780 nm to 360 nm as the retardation changes. As a result, the light transmitted through the PET film and/or the PI film results in a color distortion phenomenon in which rainbow mura is seen due to the difference in transmittance among wavelengths of visible light. Such a color distortion phenomenon becomes more significant when a viewer wears polarized sunglasses PS (see FIG. 3).

In contrast, referring to FIG. 5C, when the light, which is output from the display panel 100 (see FIG. 3) and passed through the polarizing unit PU (see FIG. 3) to be linearly polarized, passes through the high-retardation layer 223, it can be seen that the difference in the retardation versus wavelength is reduced. In other words, it can be seen that the retardation versus wavelength is uniformly distributed. Accordingly, the wavelength coincident with the absorption axis OX1 (see FIG. 3) of the polarizing unit PU (see FIG. 3) is distributed evenly over the wavelengths of 360 nm to 780 nm with very short periods. In addition, the light transmitted through the high-retardation layer 223 does not result in a color distortion phenomenon, i.e., the rainbow mura, because the difference in the transmittance among the wavelengths of the visible light is reduced. Furthermore, it is possible to effectively suppress the rainbow mura even when a viewer wears the polarized sunglasses PS (see FIG. 3). In addition, the light transmitted through the high-retardation layer 223 has very short periods and evenly distributed over the wavelengths from 360 to 780 nm, whose wavelength coincides with the absorption axis OX1 of the polarizing unit PU (see FIG. 3). Therefore, it is possible to reduce or prevent the blackout phenomenon that occurs when the light output through the flexible window 200_1 coincides with the absorption axis OX2 of the polarized sunglasses PS (see FIG. 3) such that it is not visible.

The thickness of the high-retardation layer 223 included in the flexible window 200 may be in a range from 30 nm to 80 μm. For example, if the thickness of the high-retardation layer 223 in the form of a film is less than 30 μm, it may not effectively mitigate the impact force from the outside. If the thickness exceeds 80 μm, cracks may occur when the display device is folded. Accordingly, the thickness of the high-retardation layer 223 may be in a range from 30 to 80 μm, but the present disclosure is not limited thereto.

According to an exemplary embodiment of the present disclosure, the tensile modulus of the high-retardation layer 223 may be in a range from 1 GPa to 5 GPa. By disposing the high-retardation layer 223 having a tensile modulus of 1 GPa to 5 GPa in the flexible window 200 as described above, it is possible to improve the impact resistance of the flexible window 200.

In an exemplary embodiment, a first coupling layer part CP1 may be disposed between the high-retardation layer 223 and the display panel 100 (see FIG. 1). The first coupling part CP1 may be implemented as an optically clear adhesive (OCA) film, an optically clear resin (OCR), and/or the like. In another exemplary embodiment, the first coupling part CP1 may further include a pressure sensitive adhesive (PSA). However, the present disclosure is not limited thereto. The first coupling part CP1 may serve to attach and fix the high-retardation layer 223 to the display panel 100 (see FIG. 1).

The surface layer 230 may be disposed on the high-retardation layer 223. The surface layer 230 may include a base layer 233, a hard coating layer 235 disposed on the base layer 233, and an anti-fingerprint coating layer 237 disposed on the hard coating layer 235. The second coupling part CP2 may be implemented as, but is not limited to, an optically clear adhesive (OCA) film, an optically clear resin (OCR), and/or the like. The second coupling part CP2 may serve to attach and fix the high-retardation layer 223 to the base layer 233 of the surface layer 230.

FIG. 6 is a cross-sectional view showing a stack structure of a flexible window according to another exemplary embodiment of the present disclosure.

A flexible window 200_2 of FIG. 6 is substantially identical to that described above with reference to FIG. 1 except that a retardation layer 210 is disposed between an impact mitigation layer 220 and the surface layer 230. In the following description, the redundant description will be omitted (e.g., will not be repeated) and description will be made focusing on the differences.

Referring to FIG. 6, the flexible window 200_2 may have a stack structure in which the impact mitigation layer 220 is disposed between a first coupling part CP1 and a second coupling part CP2, a retardation layer 210 is disposed between the second coupling part CP2 and a third coupling part CP3, and a surface layer 230 is disposed on the third coupling part CP3. The impact mitigation layer 220 may be formed of a polyurethane material or may be formed of a film such as PET, PC and/or acryl films.

The retardation layer 221 may have the retardation of λ/4 and may include a quarter-wave plate (QWP) that converts linearly-polarized light into circularly-polarized light, or vice versa. However, the present disclosure is not limited thereto. A λ/4 retardation film such as a reactive mesogen film may also be employed. The impact resistance of the entire flexible window 210_2 can also be improved by the impact mitigation layer 220 disposed at the bottom when the impact mitigation layer 220 is disposed at the bottom and the retardation layer 210 is disposed on it. In addition, as the retardation layer 221 disposed on the impact mitigation layer 220 converts the light that is linearly polarized through the polarizing unit PU (see FIG. 3) into a circularly-polarized light, it is possible to effectively prevent or reduce the block out phenomenon and the color distortion phenomenon which may occur when a viewer wears the polarized sunglasses PS (see FIG. FIG. 3). In other words, a viewer can watch the images on the display device 10 (see FIG. 1) stably with or without the polarized sunglasses PS.

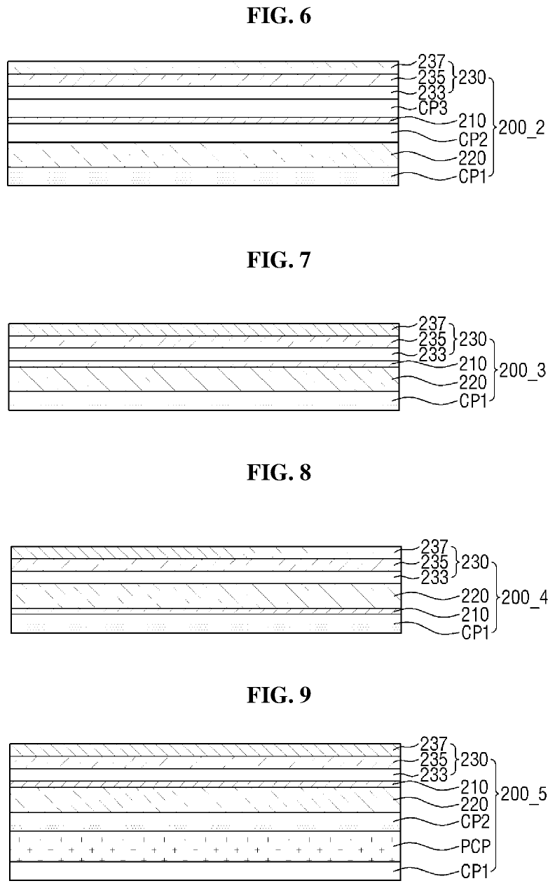

FIGS. 7 and 8 are cross-sectional views showing stack structures of flexible windows according to other exemplary embodiments of the present disclosure.

Referring to FIG. 7, in a flexible window 200_3, an impact mitigation layer 220 is disposed on a first coupling part CP1, a retardation layer 210 is disposed on the impact mitigation layer 220, and a surface layer 230 is disposed on the retardation layer 210.

For example, the second coupling part CP2 and the third coupling part CP3 may be eliminated (e.g., not included). Instead, the base layer 233 of the surface layer 230 may be utilized as a transfer substrate of the retardation layer 210, and the retardation layer 210 may be coated directly on the rear surface of the base layer 233 that is opposite to the upper surface where the hard coating layer 235 is disposed. Further, the impact mitigation layer 220 may be coated directly on the rear surface of the retardation layer 210. The impact resistance of the entire flexible window 200_3 can be improved by the impact mitigation layer 220 disposed at the bottom. In addition, as the retardation layer 221 disposed on the impact mitigation layer 220 converts the light that is linearly polarized through the polarizing unit PU (see FIG. 3) into a circularly-polarized light, it is possible to effectively prevent or reduce the block out phenomenon and the color distortion phenomenon which may occur when a viewer wears the polarized sunglasses PS (see FIG. 3). In other words, a viewer can watch the images on the display device 10 (see FIG. 1) stably with or without the polarized sunglasses PS. Moreover, by forming the retardation layer 210 and the impact mitigating layer 220 by coating, the flexible window 200_3 can be made thinner and the fabricating process can become simpler.

Referring to FIG. 8, in a flexible window 200_4, the second coupling part CP2 and the third coupling part CP3 may be eliminated (e.g., not included). Further, an impact mitigation layer 220 may be coated directly on the rear surface of the base layer 233 that is opposite to the upper surface where the hard coating layer 235 is disposed, and the retardation layer 210 may be coated directly on the rear surface of the impact mitigation layer 220.

For example, the second coupling part CP2 and the third coupling part CP3 may be eliminated (e.g., not included), the impact mitigation layer 220 may be coated directly on the rear surface of the base layer 233 that is opposite to the upper surface where the hard coating layer 235 is disposed, and the retardation layer 210 may be coated directly on the rear surface of the impact mitigation layer 220. By disposing the hard coating layer 235 and the impact mitigation layer 220 with the base layer 233 therebetween, external impact can be absorbed more effectively near the surface layer 230, so that the impact resistance of the entire flexible window 200_4 can be further improved. In addition, as the retardation layer 221 disposed under the impact mitigation layer 220 converts the light that is linearly polarized through the polarizing unit PU (see FIG. 3) into a circularly-polarized light, it is possible to effectively prevent or reduce the block out phenomenon and the color distortion phenomenon which may occur when a viewer wears the polarized sunglasses PS (see FIG. 3). In other words, a viewer can watch the images on the display device 10 (see FIG. 1) stably with or without the polarized sunglasses PS. Moreover, by forming the retardation layer 210 and the impact mitigating layer 220 by coating, the flexible window 200_4 can be made thinner and the fabricating process can become simpler.

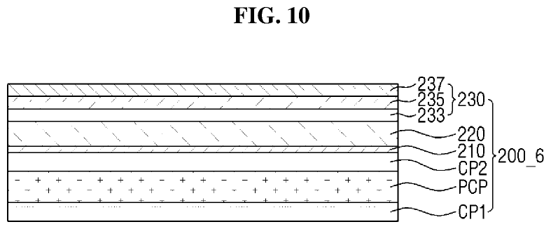

FIGS. 9 and 10 are cross-sectional views showing stack structures of flexible windows according to other exemplary embodiments of the present disclosure.

Referring to FIG. 9, a flexible window 200_5 may include a first coupling part CP1, an optical plate PCP disposed on the first coupling part CP1, a second coupling part CP2 disposed on the optical plate PCP, an impact mitigation layer 220 disposed on the second coupling part CP2, a retardation layer 210 disposed on the impact mitigation layer 220, and a surface layer 230 disposed on the retardation layer 210.

The flexible window 200_5 of FIG. 9 is substantially identical to the flexible window 200_3 of FIG. 7 except that an optical plate PCP is attached under an impact mitigation layer 220 via a second coupling part CP2. Therefore, descriptions of the identical elements will not be made to avoid redundancy.

The optical plate PCP attached under the impact mitigation layer 220 through the second coupling part CP2 may be a retardation film. The optical plate PCP may be a positive c-plate. Referring to the above-described Equations 1 to 3, the relationship between the refractive indices of the optical plate PCP may be expressed as: nz>nx=ny. By adjusting the retardation value Re in the plane direction and the retardation value Rth in the thickness direction of the optical plate PCP, it is possible to retard the phase of the light incident on the optical plate PCP after it is linearly polarized through the polarizing unit PU (see FIG. 3).

For example, in the flexible window 200_5, the base layer 233 of the surface layer 230 may be utilized as a transfer substrate of the retardation layer 210, and the retardation layer 210 may be coated directly on the rear surface of the base layer 233 that is opposite to the upper surface where the hard coating layer 235 is disposed. Further, the impact mitigation layer 220 may be coated directly on the rear surface of the retardation layer 210. The optical plate PCP may be disposed on the rear surface of the impact mitigating layer 220 through the second coupling part CP2. Accordingly, the phase of light which is linearly polarized through the polarizing unit PU (see FIG. 3) to be incident on the flexible window 200_5 is retarded by the optical plate PCP disposed under it. Further, the phase is again retarded by the retardation layer 221 disposed on the optical plate PCP. By doing so, it is possible to more effectively prevent or reduce the blackout phenomenon and the color distortion phenomenon caused when a viewer wears the polarized sunglasses PS (see FIG. 3). Furthermore, the impact mitigation layer 220 is disposed between the optical plate PCP and the retardation layer 221 to improve the impact resistance of the entire flexible window 200_5. In addition, by forming the retardation layer 210 and the impact mitigation layer 220 by coating, the flexible window 200_5 can be made thinner and the fabricating process can become simpler.

Referring to FIG. 10, a flexible window 200_6 may include a first coupling part CP1, an optical plate PCP disposed on the first coupling part CP1, a second coupling part CP2 disposed on the optical plate PCP, a retardation layer 210 disposed on the second coupling part CP2, an impact mitigating layer 220 disposed on the retardation layer 210, and a surface layer 230 disposed on the impact mitigating layer 220.

The flexible window 200_6 of FIG. 10 is substantially identical to the flexible window 200_5 of FIG. 9 except that the position of the impact mitigation layer 220 is exchanged with the position of the retarded layer 210. In other words, the flexible window 200_6 of FIG. 10 is substantially identical to the flexible window 200_5 of FIG. 9 except that the retardation layer 210 is disposed between the optical plate PCP and the impact mitigating layer 220; and, therefore, the redundant description will be omitted (e.g., will not be repeated).

While the embodiments of the present invention have been mainly described, they are merely examples and are not intended to limit the present invention. It will be understood by those of ordinary skill in the art that various modifications and applications, which are not illustrated above, can be made without departing from the essential characteristics of the embodiments of the present invention. For example, the respective components, which are specifically illustrated in the embodiments of the present invention, may be practiced with modifications. Further, the differences relating to such modifications and applications should be construed as being included in the scope of the invention as defined by the appended claims, and equivalents thereof.

What is claimed is:

1. A flexible window comprising:
a retardation layer;
an impact mitigation layer on the retardation layer; and
a surface layer on the impact mitigation layer,
wherein the retardation layer comprises a λ/4 retardation plate.

2. The flexible window of claim 1, wherein the impact mitigation layer is made of a polyurethane-based material.

3. The flexible window of claim 2, wherein a thickness of the impact mitigation layer is in a range from 70 μm to 150 μm.

4. The flexible window of claim 3, wherein a tensile modulus of the impact mitigation layer is in a range from 0.001 GPa to 0.5 GPa.

5. The flexible window of claim 4, wherein the impact mitigation layer is coated directly on a rear surface of the surface layer.

6. The flexible window of claim 5, wherein the retardation layer is coated directly on a rear surface of the impact mitigation layer.

7. The flexible window of claim 6, further comprising: a positive c-plate under the retardation layer.

8. The flexible window of claim 1, wherein the impact mitigation layer is a film made of at least one material selected from polyethylene terephthalate (PET), polycarbonate (PC), and acrylic.

9. The flexible window of claim 8, when a thickness of the impact mitigation layer is in a range from 30 μm to 80 μm, and wherein a tensile modulus of the impact mitigation layer is in a range from 1 GPa to 5 GPa.

10. The flexible window of claim 1, wherein the surface layer comprises a base layer, a hard coating layer on the base layer, and an anti-fingerprint coating layer on the hard coating layer.

11. A flexible window comprising:
a high-retardation layer; and
a surface layer on the high-retardation layer,
wherein the surface layer comprises a base layer, a hard coating layer on the base layer, and an anti-fingerprint coating layer on the hard coating layer, and
wherein an in-plane retardation of the high-retardation layer is in a range from 6,000 nm to 10,000 nm.

12. The flexible window of claim 11, wherein the high-retardation layer comprises at least one of: a cyclo-olefin polymer (COP) film, a cyclo-olefin co-polymer (COC) film, a polycarbonate (PC) film, a polyethylene terephthalate (PET) film, a polypropylene (PP) film, a polysulfone (PSF) film, and a polymethylmethacrylate (PMMA) film.

13. The flexible window of claim 12, when a thickness of the high-retardation layer is in a range from 30 nm to 80 μm, and wherein a tensile modulus of the high-retardation layer is in a range from 1 GPa to 5 GPa.

14. A flexible display device comprising:
a display panel;
a flexible window on the display panel; and
a pressure sensitive adhesive (PSA) between the display panel and the flexible window,
wherein the flexible window comprises a retardation layer, an impact mitigation layer on the retardation layer, and a surface layer on the impact mitigation layer, and wherein the retardation layer comprises a λ/4 retardation plate.

15. The flexible display device of claim 14, wherein the impact mitigation layer is made of a polyurethane-based material.

16. The flexible display device of claim 15, wherein a thickness of the impact mitigation layer is in a range from 70 μm to 150 μm.

17. The flexible display device of claim 16, wherein a tensile modulus of the impact mitigation layer is in a range from 0.001 to 0.5 GPa.

18. The flexible display device of claim 17, wherein the impact mitigation layer is coated directly on a rear surface of the surface layer.

19. The flexible display device of claim 18, wherein the retardation layer is coated directly on a rear surface of the impact mitigation layer.

20. The flexible display device of claim 19, further comprising: a positive c-plate under the retardation layer.
